(19) United States
(12) Patent Application Publication
(10) Pub. No.: US 2017/0194350 A1
(43) Pub. Date: Jul. 6, 2017

(54) LOW-NOISE MOS TRANSISTORS AND CORRESPONDING CIRCUIT

(71) Applicant: STMicroelectronics (Crolles 2) SAS, Crolles (FR)

(72) Inventor: Jean Jimenez, Salles D'aude (FR)

(73) Assignee: STMicroelectronics (Crolles 2) SAS, Crolles (FR)

(21) Appl. No.: 15/137,540

(22) Filed: Apr. 25, 2016

(30) Foreign Application Priority Data
Dec. 30, 2015 (FR) 1563454

(51) Int. Cl. H01L 27/12; H01L 29/10; H01L 29/417; H01L 29/06

(52) U.S. Cl. CPC H01L 27/1203; H01L 29/0649; H01L 29/1033; H01L 29/41758

(57) ABSTRACT

An integrated circuit includes a MOS transistor situated in and on an active region of a semiconductor substrate. The active region is bounded by an insulating region for example of the shallow trench isolation type. The drain region of the transistor is positioned in the semiconductor substrate situated away from the insulating region. An insulated gate of the transistor includes a central opening that is positioned in alignment with the drain region. A channel region of the transistor is annularly surrounds the drain region.

### PRIORITY CLAIM

This application claims priority from French Application for Patent No. 1563454 filed Dec. 30, 2015, the disclosure of which is incorporated by reference.

### TECHNICAL FIELD

Various embodiments of the invention relate to integrated circuits, and more particularly to insulated-gate (“Metal Oxide Semiconductor”: MOS) low-noise transistors notably at low frequency, in particular those fabricated in and on a substrate of the silicon-on-insulator (or SOI) type and, in particular, a substrate of the FDSOI (Fully-Depleted Silicon-On-Insulator) type.

### BACKGROUND

In general, shallow isolation trenches, commonly denoted by those skilled in the art using the acronym STI (for “Shallow Trench Isolation”), are used to define active regions of transistors. The use of shallow isolation trenches in an integrated circuit advantageously allows for an improved isolation and a reduced size.

However, an abrupt transition of the electric field occurring at the border between the active region and an isolation trench significantly influences the electrical characteristics of the transistors, for example the low-frequency noise or, in other words, the 1/f noise (or “flicker”) of MOS transistors.

Currently, the low-frequency noise may be reduced for example by a widening of the conduction channel in the neighborhood of each trench edge, obtained by the use of a gate of the butterfly type (“butterfly gate”), and/or by controlling the gate extraction energy by adding blocks known as “stickers” to each trench edge.

However, these solutions are, generally speaking, sensitive to variations in fabrication processes, such as for example photolithography alignment defects.

### SUMMARY

Thus, according to one embodiment, the aim is to reduce the 1/f noise by using a transistor structure that is less sensitive to fabrication process variations.

According to one aspect, an integrated circuit is provided, comprising at least one MOS transistor situated in and on an active region of a semiconductor substrate, the active region being bounded by an insulating region.

According to a general feature of this aspect, the drain region of the transistor is situated away from the insulating region.

Such an MOS transistor comprising such a drain region advantageously has at least one conduction channel not having any intersection with insulating regions. This feature offers a double advantage allowing not only the 1/f noise to be reduced or even eliminated, but also of not being sensitive to fabrication process variations.

According to one embodiment, the insulated gate region of the transistor has a hole so as to expose a first part of the active region situated away from the insulating region, this first part forming the drain region of the transistor, the source region of the transistor being situated within a second part of the region on either side of the gate region.

According to another embodiment, the insulating region is an insulating region of the shallow trench type.

By way of example, the substrate may be a bulk substrate or of the silicon-on-insulator type.

The substrate may also be a substrate of the fully-depleted silicon-on-insulator type.

### BRIEF DESCRIPTION OF THE DRAWINGS

Other advantages and features of the invention will become apparent upon studying the detailed description of embodiments, taken by way of non-limiting examples and illustrated by the appended drawings in which:

FIGS. 1 to 4 relate to various aspects of an electronic device.

### DETAILED DESCRIPTION

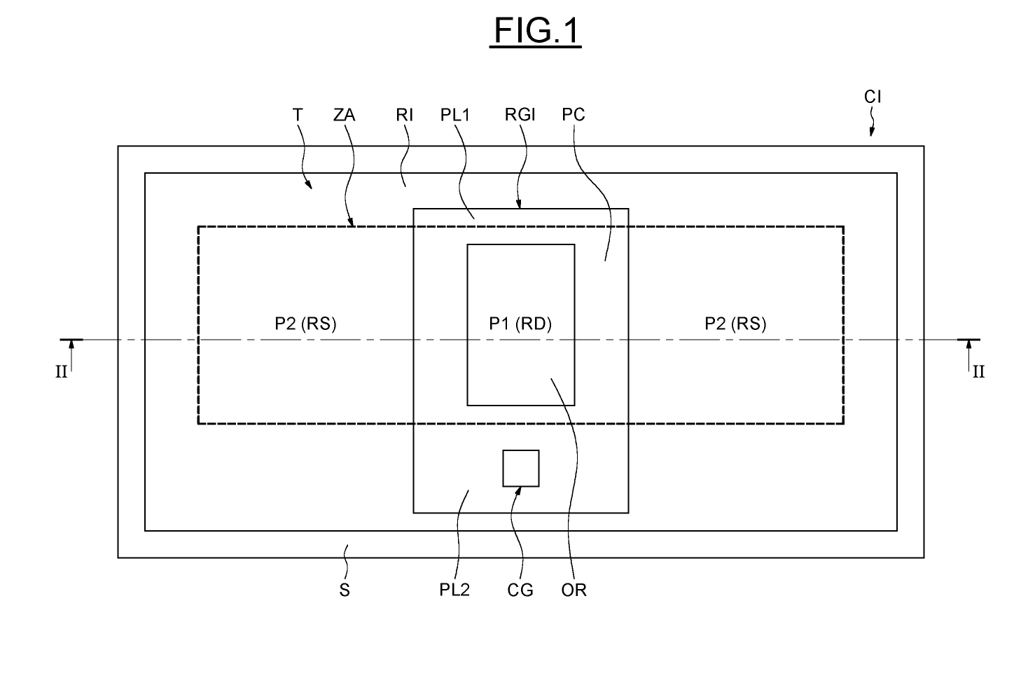

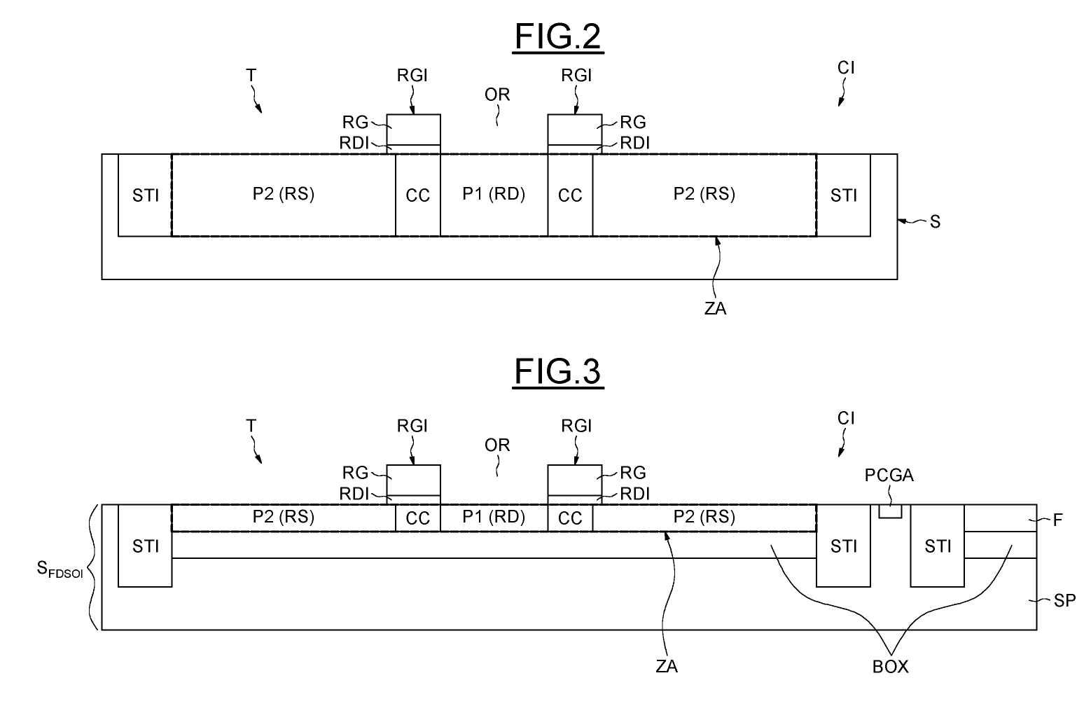

Reference is now made to FIG. 1 in order to illustrate a schematic top view of an example of an integrated circuit CI. FIG. 2 is a cross-section along the line II-II in FIG. 1.

The integrated circuit CI comprises, in this example, a transistor T, for example of the NMOS type, situated in and on an active region ZA of a semiconductor substrate S.

By way of non-limiting example, here the semiconductor substrate S is a bulk substrate.

This active region ZA illustrated by a dashed line in FIG. 1 is bounded by an insulating region RI, here a shallow trench region of the “STI” type. The latter allows an efficient isolation to be provided between devices, such as transistors, of the integrated circuit CI and a higher density of integration.

The insulated gate region RGI of the transistor T comprises a central part PC disposed on top of the active region ZA, and a first lateral part PL1 and a second lateral part PL2 in the extension of the central part PC on top of the insulating region on either side of the active region ZA. Furthermore, the second lateral part PL2 here comprises a gate contact CG.

As illustrated in FIG. 2, the insulated gate region RGI of the transistor T comprises a gate region RG disposed on a dielectric region RDI itself situated on top of the active region ZA.

A hole is furthermore formed in the central part PC of the insulated gate region RGI, in such a manner as to expose a first part P1 of the active region ZA. An orifice OR is therefore formed in the middle of the central part PC.

It should be noted that the first part P1 of the active region ZA is away from the insulating region RI, in other words from the shallow trench region STI.

The drain region RD of the transistor T is then formed in the first part P1 in such a manner as to form a central drain region which is away from the insulating region RI.

The active region ZA furthermore comprises a second part P2 situated on either side of the insulated gate region RGI and forming the source region RS of the transistor T, as can be seen in FIGS. 1 and 2.

Accordingly, the transistor T has a double conduction channel CC, situated on either side of the drain region RD on which the shallow trench region STI has little influence. The 1/f noise of the transistor T is consequently minimized.

The steps for fabricating the transistor T are conventional except that for the formation of the insulated gate region, which comprises an additional etch step, for example a dry etch, in order to locally etch the gate material and the underlying dielectric in such a manner as to expose the first part P1 of the active region ZA.

During the step for formation of a metal silicide (silicidation step) on the active region ZA, the drain region RD is silicided through the orifice OR.

Source and drain contacts (not shown in FIGS. 1 and 2 for the sake of simplification) are formed on these regions in the same way as the gate contact CG.

Furthermore, insulating spacers (not shown in FIGS. 1 and 2 for the sake of simplification) are formed in a conventional manner known per se on the outer flanks of the gate region RGI and on the inner flanks of the latter bounding the orifice OR.

As a variant, the transistor T illustrated in FIGS. 1 and 2 may also be fabricated in and on a substrate S_{FDSOI} of the fully-depleted silicon-on-insulator type, as illustrated in FIG. 3.

The references of the transistor T are unchanged since the structure of the transistor T remains the same in FIG. 3.

The substrate S_{FDSOI} comprises a semiconductor film F, for example of silicon, situated on top of a buried insulating layer BOX, commonly denoted by the acronym BOX (“Buried OXide”), itself situated on top of a carrier substrate SP, for example a semiconductor well.

One part of the semiconductor film F forms the active region ZA of the transistor T comprising the source region RS, the drain region RD, and the double channel CC situated between the drain region RD and the source region RS.

In view of the limited thicknesses of the film F, the source and drain regions are elevated by epitaxy. For the sake of simplification of FIG. 3, this elevation is not shown.

As the buried insulating layer BOX is very thin, the carrier substrate SP itself can be biased in order to provide a “back gate” region in order to control the double conduction channel CC.

For this purpose, the substrate S_{FDSOI} furthermore comprises at least one back gate contact area PCGA for example situated between two shallow trench regions STI, as illustrated in FIG. 3.

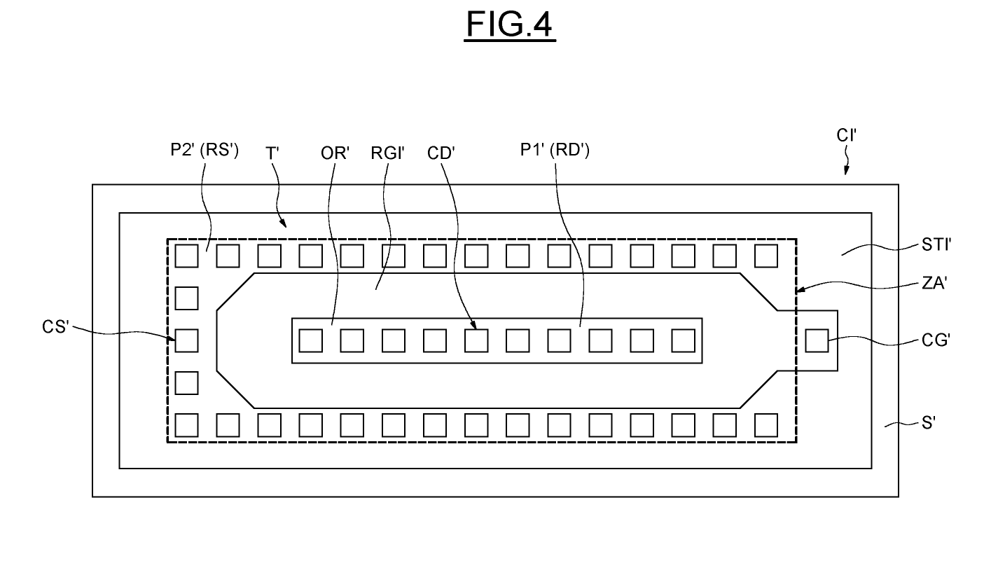

FIG. 4 illustrates a configuration diagram of another example of MOS transistor according to the invention.

As can be seen in FIG. 4, the integrated circuit CI′ comprises a transistor T′, for example of the NMOS type, situated in and on an active region ZA′ of a substrate S′.

The active region ZA′ is bounded by a shallow trench region STI′ and comprises a first part P1′ forming the central drain region RD′ of the transistor T′.

The insulated gate region RGI′ of the transistor T′ here takes the form of a ring. The insulated gate region RGI′ comprises an orifice OR′ at its center, so as to expose the first part P1′, and comprises a gate contact CG′.

The active region ZA′ furthermore comprises a second part P2′ partially surrounding the insulated gate region RGI′ and forming the source region RS′ of the transistor T′.

Advantageously, several drain contacts CD′ and source contacts CS′ are respectively formed on the drain region RD′ and the source region RS′.

As illustrated in FIG. 4, the drain region RD′ is completely surrounded by the insulated gate region RDI′ and is therefore away from the shallow trench region STI′.

Thus, a transistor T′ is obtained whose conduction channel is annular and away from the region STI′. For this reason, the 1/f noise of the transistor T′ is decreased or even eliminated.

The invention is not limited to the embodiments that have just been described but encompasses all their variants.

Thus, although transistors of the NMOS type have been described, situated in and on an active region of a bulk substrate or of a substrate of the fully-depleted silicon-on-insulator (FDSOI) type, these transistors can also be PMOS transistors. Similarly, and independently of their type, NMOS or PMOS, the transistors may be formed on any given type of substrate of the silicon-on-insulator (SOI) type, and not only of totally-depleted (FDSOI) type.

1. An integrated circuit, comprising:
a metal oxide semiconductor (MOS) transistor situated in and on an active region of a semiconductor substrate,
wherein the active region is bounded by an insulating region, and
wherein a drain region of the MOS transistor is positioned separated away from the insulating region.

2. The integrated circuit according to claim 1, wherein an insulated gate region of the MOS transistor has a hole which exposes a first part of the active region, this first part forming the drain region of the MOS transistor positioned separated away from the insulating region, and wherein a source region of the MOS transistor is positioned situated in a second part of the region on each side of the insulated gate region.

3. The integrated circuit according to claim 1, wherein the insulating region comprises a shallow trench isolation (STI) type insulating region.

4. The integrated circuit according to claim 1, wherein the semiconductor substrate is a silicon-on-insulator (SOI) type substrate. Customer No. 117381 Attorney Docket 140649-1141

5. The integrated circuit according to claim 1, wherein the semiconductor substrate is a fully-depleted silicon-on-insulator (FDSOI) type substrate.

6. The integrated circuit according to claim 1, insulated gate region of the MOS transistor has a hole positioned over the drain region of the MOS transistor.

7. An integrated circuit, comprising:
a semiconductor substrate having an active region bounded by a shallow trench isolation, the semiconductor substrate further including a drain region and a source region; and
an insulated gate positioned over the active region, said insulated gate having a central opening extending therethrough, said central opening being aligned with the drain region.

8. The integrated circuit of claim 7, wherein the semiconductor substrate further includes a channel region annularly surrounding the drain region.

9. The integrated circuit of claim 7, further comprising a drain contact extending through the central opening to make electrical contact to the drain region.

10. The integrated circuit of claim 7, wherein the semiconductor substrate is a silicon-on-insulator (SOI) substrate.

11. An integrated circuit, comprising:
a semiconductor substrate having an active region bounded by a shallow trench isolation, the semiconductor substrate further including a drain region and an annularly surrounding channel region; and
an insulated gate positioned over the active region, said insulated gate having a gate region annularly surrounding a central opening that is positioned over the drain region with the gate region positioned over the channel region.

12. The integrated circuit of claim 11, wherein the semiconductor substrate further includes a source region annularly surrounding the channel region.

13. The integrated circuit of claim 11, wherein the semiconductor substrate further includes a source region positioned between the channel region and the shallow trench isolation.

14. The integrated circuit of claim 13, wherein the source region is in contact with both the channel region and the shallow trench isolation.

15. The integrated circuit of claim 11, wherein the semiconductor substrate is a silicon-on-insulator (SOI) substrate.
